(19) United States
(12) Patent Application Publication
(10) Pub. No.: US 2024/0118632 A1
(43) Pub. Date: Apr. 11, 2024

(54) METHOD, APPARATUS AND COMPUTER PROGRAM FOR PROCESSING A SURFACE OF AN OBJECT

(71) Applicant: Carl Zeiss SMT GmbH, Oberkochen (DE)

(72) Inventors: Stefan Friedrich Rohrlack, Florstadt (DE); Bartholomaeus Szafranek, Ober-Ramstadt (DE)

(21) Appl. No.: 18/529,211

(22) Filed: Dec. 5, 2023

Related U.S. Application Data
(63) Continuation of application No. PCT/EP22/66031, filed on Jun. 13, 2022.

(30) Foreign Application Priority Data
Jun. 15, 2021 (DE) 102021206100.1

(51) Int. Cl. G03F 9/00; G03F 7/20

(52) U.S. Cl. CPC G03F 9/7057; G03F 7/2022

(57) ABSTRACT

Described are a method for processing a surface of an object, in particular of a lithographic mask, an apparatus for carrying out such a method and a computer program containing instructions for carrying out such a method.

A method for processing a surface of an object, in particular of a lithographic mask, includes the following steps: (a.) supplying a gas mixture containing at least a first gas and a second gas to a reaction site at the surface of the object; (b.) inducing a reaction, which includes at least a first partial reaction and a second partial reaction, at the reaction site by exposing the reaction site to a beam of energetic particles in a plurality of exposure intervals, wherein the first partial reaction is promoted primarily by the first gas and the second partial reaction is promoted primarily by the second gas, and wherein a gas refresh interval lies between the respective exposure intervals; (c.) setting a first time duration for the gas refresh interval, as a result of which the process rate of the first partial reaction and the process rate of the second partial reaction are present; (d.) setting a second time duration for the gas refresh interval, which brings about a relative increase in the process rate of the first partial reaction in comparison with the process rate of the second partial reaction.

### CROSS-REFERENCE TO RELATED APPLICATIONS

The present patent application is a continuation of and claims priority under 35 U.S.C. § 120 from PCT Application No. PCT/EP2022/066031, filed on Jun. 13, 2022, which claims priority from German patent application DE 10 2021 206 100.1 entitled “VERFAHREN, VORRICHTUNG UND COMPUTERPROGRAMM ZUR BEARBEITUNG EINER OBERFLÄCHE EINES OBJEKTS,” which was filed on Jun. 15, 2021, at the German Patent and Trade Mark Office. The entire contents of the above priority applications are incorporated herein by reference.

### TECHNICAL FIELD

The present invention relates to a method, to an apparatus and to a computer program for processing a surface of an object, in particular a surface of a lithographic mask, for example for repairing a defect or a plurality of defects of such a mask.

### BACKGROUND

As a consequence of the steady increase in integration density in microelectronics, lithography masks (often just “masks” for short hereinafter) have to image ever smaller structure elements into a photoresist layer of a wafer. In order to meet these requirements, the exposure wavelength is being shifted to ever shorter wavelengths. At the present time, argon fluoride (ArF) excimer lasers are principally used for exposure purposes, these lasers emitting light at a wavelength of 193 nm. Intensive work is being done on light sources which emit in the extreme ultraviolet (EUV) wavelength range (10 nm to 15 nm), and corresponding EUV masks. To increase the resolution capability of wafer exposure processes, multiple variants of conventional binary lithography masks have been simultaneously developed. Examples thereof are phase masks or phase-shifting masks and masks for multiple exposure.

However, on account of the ever decreasing dimensions of the structure elements, lithography masks cannot always be produced without defects that are printable or visible on a wafer. Owing to the costly production of masks, defective masks are repaired whenever possible.

Two important groups of defects of lithographic masks are, firstly, dark defects and, secondly, clear defects.

Dark defects are locations at which absorber or phase-shifting material is present, but which should be free of this material. These defects are repaired by removing the excess material preferably with the aid of a local etching process.

By contrast, clear defects are defects on the mask which, on optical exposure in a wafer stepper or wafer scanner, have greater transmittance than an identical defect-free reference position. In mask repair processes, such clear defects can be eliminated by depositing a material having suitable optical properties. Ideally, the optical properties of the material used for the repair and in particular those of the material produced by the repair should correspond to those of the absorber or phase-shifting material of the mask.

A possible method for repairing masks is described for example in document WO 2009/106288 A2.

However, both during the production and also during the subsequent processing of modern masks, in particular during mask repair, a plurality of partial reactions which are each induced or promoted primarily by a specific reaction gas often play a role. In known apparatuses and methods, a gas mixture in which the different reaction gases are included as a proportion is used here due to construction- and cycle time-related restrictions. These reaction gases then diffuse to the reaction site and are adsorbed here at the surface of the mask. By exposure to an energetic particle beam, the adsorbed gas molecules can be “activated”, whereupon the partial reaction promoted thereby proceeds. This can furthermore apply not only to the processing of lithographic masks, but more generally for the surface processing of objects in the field of microelectronics, for example when changing and/or repairing structured wafer surfaces or microchips or the like.

Since, as mentioned, gas mixtures have been conventionally used, the individual partial reactions in that case proceed substantially parallel to one another. However, it has therefore not been possible, or possible only with a significantly increased complexity, to selectively optimize the exposure settings and the other process parameters during the object/mask processing with respect to one of the partial reactions without the potential need to accept that the other partial processes will be negatively influenced thereby.

The present invention is therefore based on the aspect of specifying a method that makes it possible to selectively “single out” a partial process during the surface processing, in particular the mask processing, and to “amplify” it in comparison with other partial processes in order to selectively optimize the exposure process parameters for said partial process, without the need to individually introduce the respective reaction gases successively and remove them again completely before the respectively next partial process is performed. Furthermore, a corresponding apparatus and a computer program with instructions for carrying out such a method are intended to be provided.

### SUMMARY

The aforementioned aspects are at least partly achieved by the various aspects of the present invention, as described below.

In one embodiment, a method for processing a surface of an object comprises the following steps: (a.) supplying a gas mixture containing at least a first gas and a second gas to a reaction site at the surface of the object; (b.) inducing a (chemical) reaction, which includes at least a first partial reaction and a second partial reaction, at the reaction site by exposing the reaction site to a beam of energetic particles in a plurality of exposure intervals, wherein the first partial reaction is promoted primarily by the first gas and the second partial reaction is promoted primarily by the second gas, and wherein a gas refresh interval lies between the respective exposure intervals; (c.) selecting the first partial reaction to increase the process rate thereof in relation to a process rate of the second partial reaction; and (d.) selecting a time duration for the gas refresh interval, which brings about the relative increase in the process rate of the first partial reaction in comparison with the process rate of the second partial reaction.

As was already mentioned in the introductory part, the object whose surface is intended to be processed can comprise in particular a lithographic mask or be in the form of a lithographic mask. The field of application of the disclosed teaching, however, is not limited hereto, but the disclosed teaching can also be applied to the surface processing of other objects used in the field of microelectronics, for example changing and/or repairing structured wafer surfaces or surfaces of microchips, etc. Nevertheless, the text below will primarily make reference to the application relating to the processing of a mask surface so as to keep the description clearer and easier to understand. However, the other possible applications will always be encompassed here, unless explicitly ruled out or physically/technically impossible.

The disclosed method is directed at the processing of the mask (or more generally of the microelectronic object) at or near one of its surfaces. To this end, a gas mixture is supplied to the reaction site, that is to say to the site at which the processing (e.g. material removal or material deposition) is to take place. While the processing consequently takes place at the boundary region of the surface, it is certainly possible for the reaction site to also project into the mask by a depth of a few atomic layers and is therefore not only located “on” the surface (in the strict mathematical sense of a two-dimensional region). The atoms/molecules contained in the gas mixture can penetrate for example into the mask material by a specific penetration depth and be caused to react there. In other words, the “reaction site at a surface of the mask” comprises both a purely superficial processing site, but also a processing site having some depth (e.g. a depth of a few atomic layers, as described above).

The method for processing comprises a reaction having (at least) two partial reactions or partial processes, for example an etching process and a passivation process or the like (more details in this respect further below). The reaction or the partial reactions can be in particular a chemical reaction or chemical reactions. Each of the partial reactions is promoted primarily by one of the two gases that are contained in the gas mixture. “Primarily” can here be understood to mean that the partial reaction will not take place without the corresponding gas, at least not to a noticeable extent, while the partial reaction can proceed if the gas is present at the reaction site with a specific minimum concentration.

In principle, further gases and/or other substances can also take part in a corresponding partial reaction, but the main contribution to the corresponding partial reaction is made by the first or second gas. It is furthermore also conceivable that the first and/or second gas for its part includes a mixture of different partial gases. For the sake of simplicity and clarity, however, the following text will always refer to “the first gas” and “the second gas”, and the case that these are each in fact only an individual gas is explicitly possible. Specific examples of the type of gases and partial reactions that may be involved will be discussed further below.

To carry out or induce the (chemical) reaction with the partial reactions contained therein, the reaction site to which the two gases were guided is exposed to a beam of energetic particles (e.g. photons, electrons or ions), specifically in a plurality of exposure intervals. A reaction site in the context of the present disclosure can be understood to mean a pixel or, more generally, a spatial unit at which the processing process can be performed by way of exposure and inducing the reaction or the respective partial reaction(s) in a locally restrictive manner. The spatial extent of the reaction site can thus depend for example on the type of the particle beam used, the focusing thereof, the reaction type, etc.

As will be described further below, the disclosed method can furthermore certainly comprise the processing of a plurality of reaction sites (i.e. a plurality of pixels or such spatial units) in one or more exposure cycles, for example along a specific scanning pattern (within which individual reaction sites can also occur multiple times) (further details relating to the term scanning pattern further below). However, “the reaction site”, as it is used here and below, is always understood to mean a fixed location (unless specified otherwise or unless the context suggests otherwise).

An exposure interval can comprise a single, continuous exposure of the reaction site. However, a sequence of exposure flashes in rapid succession within an exposure interval would also be possible, provided such an exposure event can still be considered and described as a unit of time in a good approximation (for example if the time durations and/or distances between the exposure flashes are shorter by a multiple than the variables relating to the gas addition process (German: Gasanlagerungsprozess) and partial reactions and, as a consequence, the step-wise exposure is “not noticed” by the gas addition dynamic and the partial reactions and the reaction site).

Between the individual exposure intervals lies a gas refresh interval. Since the gas that primarily promotes this reaction is at least partially used up after the reaction site has been exposed and the first and/or second partial reaction has/have taken place in an exposure interval and therefore can no longer be present at the reaction site in a sufficient quantity and concentration, the gas refresh interval serves to resupply the corresponding gas to the reaction site in order to make it possible to once again induce the assigned partial reaction in the next exposure interval.

This is when the disclosed method intervenes and deliberately selects one of the two partial reactions in order to increase its process rate in relation to a process rate of the other partial reaction, as will be explained further below. For the sake of simplicity, the following text considers the case that the first partial reaction is selected. However, it could also be the second partial reaction, in which case the names of the two partial reactions would simply have to be swapped, and the statements that now follow would once again be accurate.

Due to the relative increase in the process rate of the selected partial reaction, it is possible to selectively “single out” this partial reaction and to adjust in this way for example the further process parameters, such as the exposure parameters (more details in this regard further below), specifically for this partial reaction. At a later time in the mask processing, the gas refresh interval can be changed (again), for example in a manner such that the second partial reaction will step into the foreground, and the process parameters are then adjusted to that partial reaction.

It should be noted at this point that an increase in the process rate of the first partial reaction in relation to the process rate of the second partial reaction does not necessarily have to mean that the process rate of the first partial reaction is then, in terms of absolute value, greater than that of the second partial reaction—although this possibility expressly exists. However, the ratio of the two process rates changes in favour of the first partial reaction in any event.

How the process rate should be quantified can here depend on the type of the participating processes/partial reactions and/or the surface processing performed. Generally, the process rate can be considered to be a “speed” with which the respective partial reaction proceeds.

With respect to an etching process/removal process rate or a deposition process, the process rate can be quantified as the material height that has been removed or deposited (instantaneously or on average) per exposure interval. A typical order of magnitude for a process rate can be in this case, for example, approximately 1 nm-150 nm per 1000 complete exposure intervals (e.g. under the assumption of a constant interval duration).

With respect to a passivation or activation process, in which a surface modification takes place (e.g. an oxidation of the surface for passivating it), the process rate can be quantified for example by a measure of the surface coverage that has already taken place. If a passivation process comprises for example oxidation of the surface, the process rate could be defined as the percentage decrease of the non-saturated bonds at the site to be processed per process run/exposure interval.

A person skilled in the art will thus understand that even if a different quantitative measure is used in each case for the process rate of the different processes/partial reactions, the relative changes in the respective process rates (expressed in % per exposure interval or per n exposure intervals, e.g. with n=10, 100 or 1000, etc.) can be compared with one another, and it is thus possible to determine whether the process rate of the first partial reaction was increased in relation to the process rate of the second partial reaction.

This change in process rates is thus not exactly effected by virtue of the fact that the two gases are guided separately to the reaction site and are removed again inbetween, or the like. Rather, the relative change in the process rates is due to a suitable selection of the gas refresh interval, i.e. the time duration that lies between two exposure intervals at the reaction site. As has already been mentioned, the two gases promoting the partial reactions are used up substantially or at least to a specific extent during an exposure interval, that is to say they have been depleted at the reaction site after the exposure interval. Although a certain residual amount may remain at the reaction site, this amount will generally be insufficient to once again promote the corresponding partial reaction to a sufficient extent in the next exposure interval. Except for individual cases, the first gas and the second gas will additionally have different physical properties (e.g. different diffusion and adsorption properties), of which the disclosed method will now take advantage: with a suitable selection or change of the time duration of the gas refresh interval, it is possible owing to the different addition dynamics of the two gases to shift the refresh process in favour of the first gas, as a result of which the process rate of the first partial reaction is relatively increased.

The relative increase in the process rate of the first partial reaction can additionally be supported by further measures, for example a change in the proportions of both gases in the gas mixture in favour of the first gas. However, this is not strictly needed for the relative increase in the process rate of the first partial reaction, which is a particular advantage of the invention.

For example, the first gas can have a first addition duration (German: Anlagerungsdauer) at the reaction site and the second gas can have a second addition duration which is greater than the first addition duration, and the time duration for the gas refresh interval can be selected such that it is lower than the second addition duration. The term “addition duration” can here be understood to mean, for example, the (hypothetical) time duration after an exposure event/exposure interval at a specific point or site, in particular the reaction site, after which the corresponding gas would have been replenished again there and been available to the same extent as it was before the exposure. In the case under consideration here, the first gas is thus a “fast” gas, while the second gas is “slower”. By selecting the time duration for the gas refresh interval to be lower than the second addition duration (but for example greater than or equal to the first addition duration, or merely somewhat lower than the first addition duration, for example greater than or equal to 50%, or 75%, of the first addition duration), it is possible to ensure that the first gas has already reached the reaction site to a noticeable extent, while the second gas is still “on the way”.

The addition durations for suitable gases, as will be described below, can here have been determined for example by experiment—possibly depending on the different types of processes for which a given gas can be used and/or in dependence on the type and nature of the object surface that is to be processed—and be used as input parameter for the method.

In theory, an encompassing and generally valid description of the steps taking place in such processes is difficult. Some details in this respect can be found in the article by Ivo Utke, et. al., “Resolution in focused electron- and ion-beam induced processing”, DOI: 10.1116/1.2789441, J. Vac. Sci. Technol. B, Vol. 25, No. 6, November/December 2007, to which express reference is made.

However, it is possible to say with some generality that at least the adsorption of the relevant gas at the surface from the gas phase and the diffusion along the surface of gas molecules from surrounding regions of the surface have an influence on the addition duration. If K and D denote the adsorption and diffusion coefficients, respectively, with respect to these steps, the addition duration can be stated for example (in a first approximation) reversely proportional to the sum of those values: τ˜(K+D)⁻¹.

If the direct adsorption as a contribution to the readdition is negligible, i.e. the readdition is mainly dependent on the diffusion coefficient, which is certainly possible, then (approximately): τ˜D⁻¹.

In addition, the addition durations are, of course, average values and the diffusion and adsorption processes are of a stochastic nature, which means that after the gas refresh interval has taken place, typically a certain amount of the second gas will also already be present at the reaction site. However, in relative terms, the first gas, and thus the first partial reaction, are preferred and consequently the process rate thereof is increased.

The time duration for the gas refresh interval can be selected in particular such that a concentration of the first gas, which has diffused to the reaction site during the gas refresh interval and has been adsorbed there at the mask surface, is greater than a concentration of the second gas.

As has already been mentioned, the disclosed method, in general terms, is directed initially only to a relative increase in the process rate of the first partial reaction in comparison with the second partial reaction. Depending on the gases used, the time duration for the gas refresh interval can, however, also be selected such that the concentration of the first gas at the reaction site in fact exceeds that of the second gas after the gas refresh interval is complete. The process rate of the first partial reaction can then also be greater, in absolute terms, than the second partial reaction.

However, it should also be mentioned that a higher concentration of the first gas at the reaction site upon exposure of the latter is not always a necessary condition for the fact that the process rate of the first partial reaction can be higher, in absolute terms, than that of the second partial reaction. Other factors, such as the type and nature of the partial reactions, the exposure intensity, etc., may also play a role here.

Starting from the time duration selected in step (d.), shortening of the gas refresh interval can result in a further relative increase in the process rate of the first partial reaction in comparison with the process rate of the second partial reaction, in particular if the first gas is, as described above, a “fast” gas in comparison with the second gas. In the reverse, lengthening the gas refresh interval can result in a relative decrease in the process rate of the first partial reaction in comparison with the process rate of the second partial reaction, because in that case the “slower” gas catches up again and the reaction it promotes therefore gains in intensity again.

The practical values for the time duration of the gas refresh interval are here of course subject to specific limits. If the time duration is chosen to be such that not even the “fastest” of the participating gases has sufficient time to again reach the reaction site to a sufficient extent, the mask processing process will stop. In addition to the gases used, this lower limit will also depend on their partial pressures in the gas mixture, the temperature at which the processing takes place, and further such factors.

A typical value of a minimum time duration for the gas refresh interval which may not be undershot is for example 10 μs or 100 μs.

Generally, typical values for the duration of the gas refresh interval, as can be used as part of the present invention, lie for example in the range from 10 μs to 30 ms, or in the range from 100 μs to 30 ms.

A typical starting value starting from which the process rates can change in relation to one another by changing the duration of the gas refresh interval, as described herein, and the two partial reactions can thus be “separated from one another” would be, for example, a gas refresh interval having a duration of 750 μs.

So to additionally explicitly single out a specific example, consideration is given to a case in which the first partial reaction is a passivation process and the first gas is H₂O, while the second partial reaction is an etching process and the second gas is XeF₂ (see also option (i), which will be discussed in more detail below, with respect to possible process/gas combinations). In this case, the passivation process can be “singled out” or “amplified” by way of a gas refresh interval having a duration in the range from 50 to 250 μs, and the etching process can be “singled out” or “amplified” by way of a gas refresh interval having a duration in the range from 600 to 1200 μs, wherein further adjustments and optimizations can be performed, if needed, within these ranges (for example in iterative test cycles/experiments) in order to obtain or further improve the desired “separation” of the partial reactions.

As another specific example, the time duration for the gas refresh interval for the relative increase in the process rate of the first partial reaction in comparison with the process rate of the second partial reaction can be selected, for example, such that it lies within the following interval I, depending on how much the process rate of the first partial reaction is intended to be distinguished, wherein the assumption here is that the first and second addition durations of the gases involved are known and/or have been experimentally determined for example in the manner indicated above:

I=[first addition duration; second addition duration)

Here, the first addition duration is the (average) addition duration of the first gas to the reaction site, and the second addition duration is that of the second gas.

The method can furthermore include adjusting one or more exposure parameters, specifically to optimize the first partial reaction.

In principle, the method can also be used to individually adjust or optimize the exposure parameters for two or even more partial reactions. However, for the sake of simplicity, the following text will discuss the case of a method having only two partial reactions, in which optimization takes place with respect to the first one.

As has already been mentioned, the disclosed method can make it possible to “single out” the first partial reaction with respect to the second partial reaction without additional structural changes or changes that relate to the gas mixture. This, in turn, can make it possible for the exposure parameter or parameters to be adjusted specifically and in a dedicated manner to the first partial process, i.e. to optimize them for the first partial reaction. Since the second partial reaction has in this case receded into the background, as it were, no deteriorations, or at least only minor deteriorations, if at all, of the second partial reaction need to be accepted, as compared with a situation in which an optimization with respect to the first partial reaction takes place without previously “singling out” this partial reaction.

For example, it is then possible, after sufficient processing of the mask (primarily) in the first partial reaction, to once again bring the second partial reaction into the foreground, for example by selecting a changed time duration for the gas refresh interval (for example a longer time duration in the region of greater than or equal to the second addition duration), and the exposure parameter or parameters can then once again be adjusted, this time with respect to the second partial reaction. In the example mentioned, according to which the second addition duration is greater than the first one, the first partial reaction could be performed in a first step, in which the second partial reaction is substantially suppressed (by selecting a shorter time duration for the gas refresh interval). However, when performing the second partial reaction (by selecting the longer time duration for the gas refresh interval) in a second step, the first partial reaction would then also proceed to a certain extent. However, by way of a prior determination before the first step, provision may be made for the entire duration of the first step for the first partial reaction to be based at least partially on the fact that the first partial reaction also proceeds during the second step. It is thus possible, for example, to make provision for a time duration of the first step (e.g. in a predetermined manner) to be dependent at least partially on a time duration and/or on exposure parameters of the second step (and, of course, vice versa).

The exposure parameter or parameters can encompass for example a duration of the individual exposure intervals for the reaction site.

The duration of the individual exposure intervals can in this case be, for example, constant while the first partial reaction is in the foreground, i.e. while its process rate is increased in relation to the process rate of the second partial reaction, but the duration can be different from the case in which the second partial reaction has been brought back (more) into the foreground.

The duration for the individual exposure intervals, however, can also vary from interval to interval, while the process rate of the first partial reaction is relatively increased, or between different blocks of intervals, etc.

As has already been mentioned, it is additionally also possible that the disclosed method comprises the processing of a plurality of reaction sites (e.g. a plurality of pixels), which are exposed to the beam of energetic particles within an exposure cycle during one or more respective exposure intervals.

Within such an exposure cycle, the reaction sites can be run through, for example, one after the other and be exposed to the beam of energetic particles during a respective exposure interval in order to thus trigger and perform the processing reaction(s) at the respective reaction site. It is here, however, also possible that specific reaction sites are processed within an exposure cycle not only once but multiple times (e.g. reaction sites at which particularly strong processing is needed), wherein different numbers of repetitions within an exposure cycle are possible for different reaction sites. For such reaction sites that have been exposed multiple times, the duration of the individual exposure intervals within a given exposure cycle additionally does not need to be constant, but it can actually vary over the cycle.

The method can comprise a plurality of such exposure cycles. These can be run through successively.

The duration of the exposure intervals for the individual reaction sites/pixels is also referred to in technical terminology as “dwell time (DWT)” with respect to the corresponding reaction site/pixel.

The exposure parameter or parameters that can be adjusted specifically to optimize the first partial reaction can in this case also encompass a duration of the respective exposure intervals for the individual reaction sites.

The exposure of individual reaction sites (e.g. pixels) or clusters of reaction sites (e.g. clusters of pixels) can thus be controlled and set individually, wherein this may also vary from cycle to cycle. The exposure can in this way be set to the first partial reaction with particular accuracy and be optimized for it, which may offer significant advantages for example if the method is applied to a mask repair, because this requires highly accurate and delicate work to achieve the desired correction effect.

The exposure parameter or parameters that can be adjusted specifically to optimize the first partial reaction can furthermore include a scanning pattern, with which the reaction sites can be exposed one after the other within such an exposure cycle.

Such a scanning pattern makes it possible to specify the order in which the individual reaction sites (or clusters of reaction sites) are run through during the processing.

An adjustment of the scanning pattern specifically to the first partial reaction can consist, for example, in that the first partial reaction is to relate to only a smaller region in comparison with the second partial reaction—or, for example in terms of pixels, to only a subset of all the pixels. The scanning pattern can then be selected accordingly and be expanded to the larger region at a later point in time (for example when the process rate of the second partial reaction has been increased again).

The scanning pattern can also include one or more subloops which are run through more than once during an exposure cycle, with the result that the reaction sites contained in the subloops are exposed multiple times within an exposure cycle, as was already explained above.

This can, for example, be advantageous in particular if individual reaction sites or clusters of reaction sites under the first partial reaction require particularly intensive processing. At least assuming that there is always enough of the first gas at the corresponding reaction sites (e.g. when the first gas is “fast enough”), these reaction sites can then be run through multiple times within an exposure cycle to save time.

A change in such a scanning pattern and/or the subloops(s) contained therein can likewise be used “indirectly” to influence the duration of the gas refresh interval with respect to a specific reaction site and consequently the relative process rates of the first and second partial reactions at said site. If, for example, a specific reaction site is targeted multiple times within an exposure cycle, the number of the other reaction sites lying in each case between the exposure intervals for the reaction site under consideration will have an influence on the gas refresh interval with respect to the reaction site under consideration, which, after all, in accordance with the disclosure denotes the time duration between two exposure intervals/events at said fixed site. So if, for example, the subloops(s) are shortened, fewer other reaction sites will be processed between two exposure intervals at the reaction site under consideration, which can shorten the time duration for the gas refresh interval with respect to the reaction site under consideration and can thus increase the process rate of the first partial reaction in comparison with that of the second partial reaction (for example when the first gas is a “faster” gas than the second gas). A decrease in the number of the reaction sites that are processed in the first place within an exposure cycle can also have this effect, because here, too, a smaller number of other reaction sites need to be processed between two exposure intervals of a relevant reaction site.

All of this does not, of course, rule out that the choice of the time duration for the gas refresh interval can also be made such that actual waiting times are part of the method during which no exposures at all occur, unless at the reaction site under consideration itself, or at any further reaction sites that may be present and also processed as part of the method, as has just been described.

As a specific example, the scanning pattern can include for example a plurality of subloops, which are run through successively. Each reaction site, for example each pixel of the area selected for processing, can here be assigned to exactly one subloop and be exposed therein exactly once, wherein adjacent pixels are assigned to different subloops. For example, there may be n subloops, wherein only every n-th pixel is exposed in each subgroup. Once all subloops have been run through, all the pixels will have been exposed, i.e. processed, exactly once. The area to be processed and the sequence of subloops and also the assignment of the pixels to the latter can now be selected such that the selected gas refresh interval would have just passed between two exposures of a given pixel. If appropriate, the duration of the exposure intervals for the individual pixels and/or any waiting times between the exposure intervals can also be adjusted in this respect. In this way, the first partial reaction can then be used and performed in a particularly effective and time-saving manner.

In addition or alternatively to the abovementioned possibility, further measures can also be taken, as already mentioned above, in order to increase the process rate of the first partial reaction in relation to the second partial reaction, that is to say in order to even better “single out” the first partial reaction. One possibility that has already been mentioned would be, for example, to change the respective proportions of the two gases in the gas mixture used. A further, additional or alternative possibility consists of heating the reaction site (or the reaction sites) using a pulsed laser to further influence the process rates of the individual partial reactions.

This presupposes a certain temperature dependence of the two partial reactions. For example, if the first partial reaction is preferred by higher temperatures, heating can make it possible to even better single out the first partial reaction with respect to the second partial reaction. In the reverse case, heating by laser can be used in order to once again “add”, as it were, the second partial reaction as desired without the need to change the gas refresh interval.

In other words, in that case there are two setscrews—the time duration for the gas refresh interval between two exposure intervals at the reaction site and the degree of heating thereof by the pulsed laser—for being able to set the relative intensity of the two partial reactions at the reaction site. This in turn can make particularly exact adjustment of the exposure parameters and, more generally, a particularly targeted process control and processing sequence possible.

If the method involves a plurality of reaction sites, it is possible thereby to achieve a further local fine adjustment of the process rates by differently heating the different reaction sites.

The beam of energetic particles can be a laser beam.

The use of a laser beam can be advantageous since laser apparatuses are readily available on the market in many forms and can be quite inexpensive.

The beam of energetic particles can be an electron beam.

Being a beam of particles that have mass, an electron beam can offer a high spatial resolution (i.e. cause, for example, a small spatial extent of the reaction site). At the same time, the use of electrons can allow conclusions to be drawn relating to the progress of the processing by way of the measurement of backscattered electrons and/or secondary electrons during the mask processing.

The beam of energetic particles can also be an ion beam.

An ion beam may offer an even better spatial resolution than an electron beam, but beam guidance may be more complicated in this case and unintended changes of or damage to the mask during processing might also possibly play a larger role.

The first partial reaction can comprise at least one of the following processes: a passivation process, an etching process, a deposition process, an oxidation process.

The second partial reaction can comprise at least one of the following processes: a passivation process, an activation process, an etching process, a deposition process.

The method or the induced (chemical) reaction can also include a third partial reaction, which is mainly promoted by a third gas contained in the gas mixture (a fourth, fifth etc. partial reaction promoted mainly by a fourth, fifth etc. gas is likewise feasible).

Similarly, the method can also include scenarios in which a first gas refresh interval is set such that the first partial reaction is favored (compared to the second partial rection), e.g. primarily an etching process occurs. Subsequently, a second gas refresh interval may be set such that the second partial reaction is favored, e.g. primarily a passivation process occurs. Subsequently, the first gas refresh interval (or a similar third gas refresh interval) may be set again to favor the first partial reaction once again. Subsequently, the second gas refresh interval (or a similar fourth gas refresh interval) may be set again to favor the second partial reaction once again Hence, first and second partial reactions may be implemented in an alternating fashion, e.g. at least two times, at least three times, at least four time, more than five times, more than ten times, etc.

For example, when a first gas refresh interval is set, a processing rate of the first partial reaction (e.g. an etching process) and a second processing rate of the second partial reaction (e.g. a passivation process) may be provided. Then, the first or second partial reaction may be selected, and a second gas refresh interval may be set, based on the selected partial reaction, such that the processing rate of the selected partial reaction may be increased compared to the processing rate of the non-selected partial reaction. For example, the first gas refresh interval (or a similar third gas refresh interval) may be set to again relatively reduce the processing rate of the selected partial reaction compared to the processing rate of the non-selected partial reaction, and so forth. Hence, first and second partial reactions may be implemented in an alternating fashion.

Exemplary combinations comprised by the present invention are as follows:

(i) The first partial reaction is a passivation process and the second partial reaction is an etching process.

The first gas used, i.e. in the form of a passivation gas, can here be, for example, H₂O.

The second gas used, i.e. in the form of an etching gas, can be, for example, XeF₂. The second gas can furthermore possibly include admixtures of MoCO and/or NH₃ in small amounts.

This combination is suitable, for example, when processing HD-PSM materials and HD PSM masks.

(ii) The first partial reaction is an oxidation of the mask surface at the reaction site and the second partial reaction is an etching process.

Here, the first gas used, i.e. in the form of an oxidation gas, can be, for example, nitrous gases (e.g. N₂O, NO, NO₂), hydrogen oxides (e.g. H₂O, H₂O₂), molecular or atomic oxygen, and/or ozone.

The second gas used, i.e. in the form of an etching gas, can be, for example, halogen-containing compounds/halides such as halogens (e.g. F₂, Cl₂), hydrogen halides (e.g. HF, HCl), noble gas halides (e.g. XeF₂), nitrogen halides (e.g. NF₃, NOF, NCl₃, NOCl), halogenated hydrocarbons (e.g. CF₄, CHF₃, CCl₄), phosphorus halides (e.g. PF₃, PCl₃), and/or sulfur halides (e.g. SF₆, SF₄, SF₂, SCl₂, thionyl chloride).

(iii) The first partial reaction is an oxidation of the mask surface at the reaction site and the second partial reaction is an etching process. The method or the induced reaction furthermore comprises a third partial reaction, primarily promoted by a third gas contained in the gas mixture, wherein the third partial reaction is a passivation process.

Here, the first gas used, i.e. in the form of an oxidation gas, can be, for example, nitrous gases (e.g. N₂O, NO, NO₂), hydrogen oxides (e.g. H₂O, H₂O₂), molecular or atomic oxygen, and/or ozone.

The second gas used, i.e. in the form of an etching gas, can be, for example, halogen-containing compounds/halides such as halogens (e.g. F₂, Cl₂), hydrogen halides (e.g. HF, HCl), noble gas halides (e.g. XeF₂), nitrogen halides (e.g. NF₃, NOF, NCl₃, NOCl), halogenated hydrocarbons (e.g. CF₄, CHF₃, CCl₄), phosphorus halides (e.g. PF₃, PCl₃), and/or sulfur halides (e.g. SF₆, SF₄, SF₂, SCl₂, thionyl chloride).

The third gas used, i.e. as a passivation gas, can be, for example, metal carbonyls (e.g. Mo(CO)₆, Cr(CO)₆, W(CO)₆, Fe(CO)₅), H₂O, nitrous gases (e.g. N₂O, NO, NO₂), and/or silicon-containing compounds (e.g. silicates (e.g. TEOS=tetraethyl orthosilicates), silicon isocyanates (e.g. tetraisocyanatosilanes), silanes (e.g. cyclopentasilane), siloxanes and/or silazanes).

(iv) The first partial reaction is a deposition process and the second partial reaction is a further reaction to give the desired deposition product.

Here, the first gas used, i.e. as a deposition gas, can be, for example, silicon-containing compounds (e.g. silicates (e.g. TEOS=tetraethyl orthosilicates), silicon isocyanates (e.g. tetraisocyanatosilane), silanes (e.g. cyclopentasilane), siloxanes and/or silanes)) and/or metal carbonyls (e.g. Mo(CO)₆, Cr(CO)₆, W(CO)₆, Fe(CO)₅).

The second gas used, i.e. as a reactant, can be, for example, NH₃ as a nitriding agent and/or e.g. H₂O or NO₂ as an oxidant. Nitrous gases (e.g. N₂O, NO, NO₂), hydrogen oxides (e.g. H₂O, H₂O₂), molecular or atomic oxygen and/or ozone are also feasible as the second gas.

(v) The first partial reaction is a deposition process and the second partial reaction is a cleaning process.

Here, the first gas used, i.e. in the form of a deposition gas, can be, for example, organometallic compounds (e.g. Pt-, Pd-, Ru-, Re-, Rh-, Ir-, and/or Au-containing precious-metal compounds or Cu, Ni, Co, Fe, Mn, Cr, Mo, W, V, Nb, Ta, Zr, Hf compounds).

The second gas used, i.e. in the form of a cleaning gas, can be, for example, H₂O or NO₂ for oxidation. Furthermore conceivable here are nitrous gases (e.g. N₂O, NO, NO₂), hydrogen oxides (e.g. H₂O, H₂O₂), molecular or atomic oxygen and/or ozone. Alternatively or additionally, the second gas used can be e.g. NOCl or XeF₂ for halogenation. Also feasible here are halogen-containing compounds/halides such as halogens (e.g. F₂, Cl₂), hydrogen halides (e.g. HF, HCl), noble gas halides (e.g. XeF₂), nitrogen halides (e.g. NF₃, NOF, NCl₃, NOCl), halogenated hydrocarbons (e.g. CF₄, CHF₃, CCl₄), phosphorus halides (e.g. PF₃, PCl₃), and/or sulfur halides (e.g. SF₆, SF₄, SF₂, SCl₂, thionyl chloride).

In a third partial reaction, the non-vacuum-resistant oxygen or halogen compounds may then possibly disintegrate and leave behind pure metal compounds.

At this point it is emphasized that the combination of partial reactions mentioned as option (v) (i.e. that the first partial reaction is a deposition process and the second partial reaction is a cleaning process, using the gases mentioned and possibly also using a third partial reaction in which the non-vacuum-resistant oxygen or halogen compounds disintegrate and leave behind pure metal compounds) represents its own invention, which can also be claimed without the selection and manipulation of the relative process rates and the gas refresh interval, as described herein. Consequently, the present disclosure comprises as its own invention for example a modified method that includes the steps (a.), (b.), (b1.) and (b2.) already described, but not necessarily also steps (c.) and/or (d.), and in which the partial reactions mentioned as option (v) take place. All other optional method steps and possible modifications described herein can be likewise combined with this modified method, even if this has not been explicitly mentioned and discussed here for the sake of conciseness. Analogous statements also apply with respect to an apparatus and software for performing such a modified method (cf. in this respect the corresponding statements that follow).

In particular, the disclosed method can serve for correcting a defect of the mask (or of a wafer/chip surface or the like, see the statements made in the introductory part). Since a great accuracy regarding the individual processing steps is necessary herefor—in particular in modern masks and with respect to the continuously increasing integration density—the option of selectively controlling and singling out individual partial reactions offers new possibilities for optimizing the individual partial reactions, for example with respect to the exposure parameters used.

At this point, it is further mentioned that although the possible features, options and modification options of the disclosed method were described in a certain sequence herein, this should not necessarily express a specific dependence of the features among themselves—unless this was explicitly presented in this way. Rather, the various features and options can also be combined in other sequences and permutations—to the extent that this is possible from a physical and technical point of view—and such combinations of features or even sub-features are also encompassed by the present invention. Individual features or sub-features can also be omitted, provided they are not required to obtain the desired technical result.

An apparatus for processing an object, in particular a lithographic mask, includes, in one embodiment, (a.) means for supplying a gas mixture containing at least a first gas and a second gas to a reaction site at a surface of the object; (b.) means for inducing a (chemical) reaction, which includes at least a first partial reaction and a second partial reaction, at the reaction site by exposing the reaction site to a beam of energetic particles in exposure intervals, wherein the first partial reaction is promoted primarily by the first gas and the second partial reaction is promoted primarily by the second gas, and wherein a gas refresh interval lies between the respective exposure intervals; (c.) means for selecting the first partial reaction to increase the process rate thereof in relation to a process rate of the second partial reaction; and (d.) means for selecting a time duration for the gas refresh interval, which brings about the relative increase in the process rate of the first partial reaction in comparison with the process rate of the second partial reaction.

In general terms, it is an advantage of the disclosed method that targeted influencing of individual partial reactions becomes possible without any need for a fundamentally new construction of the apparatuses used for the performance. For example, the apparatus described here can proceed, if it is intended for use, for example, for mask repair, from one of the apparatuses for mask repair developed and sold by the applicant.

However, according to current knowledge of the applicant, the deliberate choice of individual partial reactions was not provided in prior apparatuses. In contrast, the apparatus described here allows the deliberate picking of one of the partial processes involved, by way of a suitable and targeted selection of the time duration for the gas refresh interval, as described in detail above as part of the discussion of the disclosed method.

In particular, the apparatus can automatically select the time duration for the gas refresh interval based on the selection of the first partial reaction for relatively increasing its process rate.

The first gas can thus, for example, have a first addition duration to the reaction site and the second gas can have a second addition duration, and the means for selecting the time duration for the gas refresh interval choose the time interval on the basis of the first and second addition durations in a manner such that the relative increase in the process rate of the first partial reaction in comparison with the process rate of the second partial reaction takes place, as described above. As mentioned, this can be done automatically. The relevant values and data, for example the first and second addition durations for the first and second gases used, can here be available to the apparatus in the form of stored values and/or be obtained from a database. Alternatively, the apparatus contains suitable means for determining these values experimentally, either during running operation (i.e. during the processing of the mask itself), or in a dedicated test mode.

Finally, a computer program can include instructions that, upon execution, cause a computer or a computer system to carry out the steps of one of the embodiments of the method disclosed.

### BRIEF DESCRIPTION OF DRAWINGS

The following detailed description describes possible embodiments of the invention, with reference being made to the figures, wherein

FIGS. 1A-1C schematically show a mask and different points in time during the processing using an embodiment of the disclosed method; and

FIG. 2 shows a schematic diagram of an embodiment of an apparatus, as can be used for carrying out the disclosed method.

### DETAILED DESCRIPTION

Below, embodiments of the present invention are predominantly described with reference to repairing a lithographic mask. However, the invention is not restricted thereto and can also be used for other types of masks processing, or, even more generally, for the surface processing of other objects used in the field of microelectronics, for example for changing and/or repairing structured wafer surfaces or surfaces of microchips, etc. Even if the following text therefore primarily makes reference to the application in the case of the processing of a mask surface in order to keep the description clearer and more easily understandable, the other application possibilities of the disclosed teaching will still be clear to a person skilled in the art.

Further, reference is made to the fact that only individual embodiments of the invention can be described in more detail below. However, a person skilled in the art will appreciate that the features and modification options described in conjunction with these embodiments can also be modified further and/or can be combined with one another in other combinations or sub-combination without this leading away from the scope of the present invention. Moreover, individual features or sub-features can also be omitted, provided they are dispensable in respect of achieving the desired result. In order to avoid unnecessary repetition, reference is therefore made to the remarks and explanations in the preceding sections, which also retain their validity for the detailed description which now follows below.

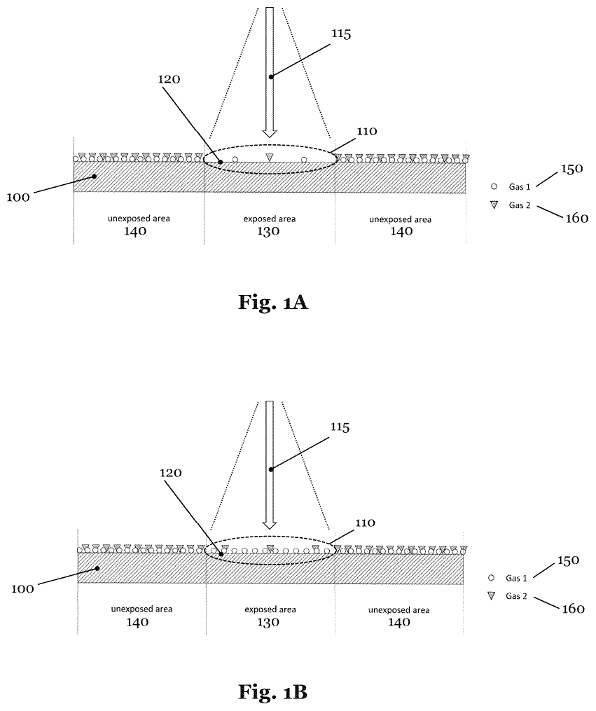

FIGS. 1A-1C schematically illustrate how the time duration of the gas refresh interval is used to relatively increase the process rate of a first partial reaction in comparison with a second partial reaction as part of an embodiment of the invention.

The method shown serves for processing a lithographic mask 100 (or of another microelectronic object, e.g. a wafer or microchip). For processing the mask 100, a gas mixture is supplied to a reaction site 110 at the surface 120 of the mask 100. As has already been mentioned, the reaction site 110 can here substantially lie on the surface 120 of the mask 100 or extend into the mask 100 up to a specific depth (e.g. a depth of a few atomic layers). In addition, the surface 120 and thus also the reaction site 110 will generally change slightly during the processing, for example during an etching or deposition process during the mask repair.

The processing takes place in a manner such that the reaction site 110 is exposed to a beam of energetic particles in a plurality of exposure intervals, said beam being indicated in FIGS. 1A-1C by the arrow 115 and the dotted lines to the left and right thereof. The beam 115 can be, for example, a laser beam, or an electron beam, or an ion beam.

In FIGS. 1A-1C, the mask 100 is schematically divided into a part 130 (referred to as “exposed area”), which is subjected to the exposure and comprises the reaction site 110 at the mask surface to be processed, and adjacent regions 140 (referred to as “unexposed area”), which are not subjected to the exposure and on which no processing will take place in the embodiment discussed here. The regions 140 can likewise be processed in further processing steps (e.g. by successively running through a plurality of reaction sites along a scanning pattern over one or more cycles; however, this is not shown in FIGS. 1A-1C for the sake of simplicity).

As was already explained in the introductory part, the term “reaction site” as part of the present disclosure is here understood to mean a pixel or, more generally, a spatial unit at which the processing process can be performed by way of exposure and inducement of the respective partial reaction(s) in a locally restricted manner. The spatial extent of the reaction site can thus depend for example on the type of the particle beam 115 used, its focusing, the reaction type, etc. It should be noted here that the depictions of FIGS. 1A-1C are merely schematic illustrations, which do not necessarily have to reflect the conditions that occur in reality to scale.

The gas mixture supplied to the reaction site 110 contains in the embodiment shown here two gases, specifically a first gas 150, which is denoted by “Gas 1” in FIGS. 1A-1C and whose gas atoms or molecules are illustrated schematically by the symbol “o” (open circle), and a second gas 160, which is denoted by “Gas 2” in FIGS. 1A-1C and whose gas atoms or molecules are schematically illustrated by the symbol “V” (a solid grey triangle pointing downwards). Each of the two gases 150 and 160 here predominantly promotes a separate partial reaction involved in the mask processing, i.e. the mask processing includes a (chemical) reaction with a first partial reaction, which is predominantly promoted by the gas 150, and a second partial reaction, which is promoted predominantly by the gas 160. As has already been described above, “predominantly” can here be used to mean that without the corresponding gas, the partial reaction will not take place, at least not to a noticeable extent, while the partial reaction can proceed if the gas is present at the reaction site at a specific minimum concentration. The (chemical) reaction with the partial reactions included therein is induced, i.e. triggered or started, by the exposure to the beam 115 of energetic particles.

It should be noted at this point that the gas mixture supplied to the reaction site 110 in other embodiments can also include further gases, for example a third gas, which predominantly promotes a third partial reaction, etc. For the sake of simplicity, however, only two gases 150 and 160 and the corresponding two partial reactions will be mentioned below.

The gas 150 and/or the gas 160 can additionally also itself represent a gas mixture.

FIG. 1A schematically shows the state after an exposure interval, i.e. after the reaction site 110 was exposed to the beam 115 of energetic particles. As can be seen, the first and second partial reactions were triggered by the exposure, and both the gas 150 (“°”) and also gas 160 (“ [symbol] ”) were substantially used up by the progression of the two partial reactions, and the gases are therefore depleted at the reaction site 110 or no longer present at all.

In order to be able to once again allow the processing reaction with its partial reactions to proceed (the mask processing typically includes a number of processing run-throughs because for example an etching or depositing process cannot be performed with the desired accuracy in a single run-through), gas needs to be therefore supplied again. For this purpose, a gas refresh interval is used, which lies between the individual exposure intervals. During said gas refresh interval, the gases 150 and 160 contained in the gas mixture used diffuse to the reaction site 110 and are adsorbed there and/or near the surface 120 of the mask 100 (the gas atoms/molecules may also penetrate into the mask 100 by a specific penetration depth).

According to the invention, one of the two partial reactions is now deliberately and selectively singled out in order to increase the process rate thereof in relation to the process rate of the other partial reaction. For the sake of clarity, the partial reaction that is singled out and selected for increasing the process rate thereof will here always be referred to as the first partial reaction.

In order to bring about the relative increase in the process rate of the first partial reaction in comparison with the second partial reaction, the time duration for the gas refresh interval is suitably selected or adjusted. FIG. 1B schematically shows the state after the gas refresh interval thus selected has passed.

The two gases 150 and 160 shown here differ in terms of their physical and chemical properties. Firstly, the two gases 150 and 160 promote different partial reactions, as was already mentioned. Secondly, however, they also have different diffusion and adsorption properties with respect to the mask surface 120 at the reaction site 110. The result of this is that the two gases 150 and 160 have different addition durations, i.e. the time duration they require in order to be “refreshed” again to a sufficient extent at the reaction site 110 differs (these are generally mean values, of course, as is typical in such thermodynamic processes).

In the present case, the gas 150 is a “fast” gas, while the gas 160 is a “slower” gas, i.e. the gas 150 has a shorter addition duration to the mask surface 120 at the reaction site 110 than the gas 160. Consequently, the first gas 150 already had, during the selected gas refresh interval, which for example is selected to be shorter here than the second addition duration or was selected in particular within the following interval

I=[first addition duration; second addition duration)

sufficient time to replenish itself again at the reaction site 110 at the mask surface 120 to an extent such that the first partial reaction can once again be triggered and performed by exposure to the particle beam 115. By contrast, no sufficient amount, or at least only a small amount, of the second gas 160 has been able to replenish itself at the reaction site 110, with the result that the second partial reaction can proceed only to a noticeably smaller extent (if at all) as compared with the situation in FIG. 1A.

In the case indicated in FIG. 1B, the concentration of the gas 150, which has diffused to the reaction site 110 and been adsorbed there, is here greater than the concentration of the gas 160 after the gas refresh interval has passed.

Owing to this selection of the time duration of the gas refresh interval, the process rate of the second partial reaction is suppressed with respect to the process rate of the first partial reaction, without the need to change for example anything about the gas mixture introduced for this purpose (although this would also be conceivable as an alternative or in addition to the approach described here in order to amplify one of the two partial reactions over the other one). The other way round, the desired relative increase in the process rate of the first partial reaction in comparison with the second partial reaction is thus achieved via the time duration selected for the gas refresh interval.

It should be noted at this point that it is possible in principle that even in the case shown in FIG. 1B the absolute process rate of the second partial reaction is still greater than the absolute process rate of the first partial reaction. This will generally depend on further factors, for example on the nature of the two partial reactions, the mask material, etc. However, a relative shift in the two process rates in favour of the first partial reaction takes place at any event. A conceivable numerical measure for quantifying this is for example the quotient of the absolute process rate of the first partial reaction to the second partial reaction, which increases in the case shown. However, it is expressly also possible that the process rate of the first partial reaction will become greater in absolute terms than the process rate of the second partial reaction.

Proceeding from the situation indicated in FIG. 1B (or a similar situation), shortening the time duration of the gas refresh interval can result in a further relative increase in the process rate of the first partial reaction in comparison with the process rate of the second partial reaction, even if this might be connected at the same time with a decrease in the absolute process rate of the first partial reaction. In this case, the time duration of the gas refresh interval can also be selected to be shorter than the first addition duration, for example ≥50% of the first addition duration or ≥75% of the first addition duration. However, any further shortening of the time duration of the gas refresh interval is also subject to a specific lower limit (for example at 50% of the first addition duration), because below said time duration, the first gas 150 is no longer “fast” enough, and in that case both partial reactions will in fact stop.

On the other hand, lengthening of the time duration for the gas refresh interval starting from the situation indicated in FIG. 1B (or a similar situation) can again shift the balance in favour of the second partial reaction, i.e. lead to a relative decrease in the process rate of the first partial reaction in comparison with the process rate of the second partial reaction, i.e. to a relative increase in the process rate of the second partial reaction in comparison with the process rate of the first partial reaction. As an example of this case, FIG. 1C shows the situation for the selection of a long time duration for the gas refresh interval (compared with the time duration that has led to the situation in FIG. 1B), in which both the first gas 150 and also the second gas 160 have replenished again at the reaction site 110 to a noticeable extent. In comparison with the state in FIG. 1B, the process rate of the second partial reaction will thus be significantly increased. Even though the process rate of the first partial reaction can also be slightly increased in comparison with FIG. 1B, the ratio of the process rates in FIG. 1C have at any event once again shifted in the direction of the second partial reaction. In the limit case, with a sufficiently long gas refresh interval, it is possible here for a saturation state to occur, in which both gases 150 and 160 are adsorbed at the reaction site 110 in a saturated concentration, with the result that further lengthening of the gas refresh interval will no longer lead to a noticeable change in the (relative) process rates.

Alternatively or in addition to the mechanisms described here, it is furthermore possible to heat up the reaction site 110 or the mask 100 and/or mask surface 120 in this region for example using a pulsed laser in a targeted and controlled manner and to thereby influence the process rates of the first and second partial reactions in absolute terms and/or relative to one another. It is possible here for example for the process rates of the partial reactions themselves to be dependent on the temperature, or they can be influenced indirectly by the heating via a temperature dependence of the diffusion and adsorption properties of the gases 150 and 160, or by a combination of direct and indirect influencing.

After the process rate of the first partial reaction has now been increased for example as indicated in FIG. 1B in relation to the process rate of the second partial reaction, for example one or more exposure parameters used for the exposure of the reaction site 110 to the particle beam 115 can be adjusted and set in a manner such that specifically the first partial reaction is optimized. As has already been described in detail above, this can encompass different parameter (combinations) and approaches. For example, the exposure durations of the plurality of exposure intervals can be adjusted.

Furthermore, the method can comprise processing a plurality of reaction sites (not shown in FIGS. 1A-1C) which are exposed to the beam 115 of energetic particles within an exposure cycle during one or more respective exposure intervals. The method preferably encompasses a plurality of such exposure cycles. In this case, the one or more exposure parameters that are used in the exposure to the particle beam 115 can comprise a duration of the respective exposure intervals for the individual reaction sites. The one or more exposure parameters can also include a scanning pattern, with which the reaction sites are exposed one after the other. Such a scanning pattern can also include one or more subloops. The latter can be run through exactly once during an exposure cycle. However, one or more of the subloops can also be run through more than once during an exposure cycle, with the result that the reaction sites contained in these subloops will be exposed multiple times in an exposure cycle. Details in this respect were discussed in section 3, to which reference is made in this respect.

The first partial reaction can comprise, for example, a passivation process, an etching process, a deposition process or an oxidation process. The second partial reaction can comprise, for example, a passivation process, an activation process, an etching process or a deposition process. In addition, the processing of the mask 100 can comprise a third partial reaction, which is predominantly promoted by a third gas, etc.

Specific possibilities and partial reaction combinations and gases that are suitable therefor were already described above as possible combinations “(i)”, “(ii)”, “(iii)”, “(iv)” and “(v)”, and reference is therefore made to the above embodiments for the sake of conciseness.

In addition, the separate invention content of option (v), has been repeatedly pointed out, as was already explained further above.

In conclusion, reference is once again made to the fact that the method can be used in particular for correcting a defect of the mask 100, that is to say for mask repair.

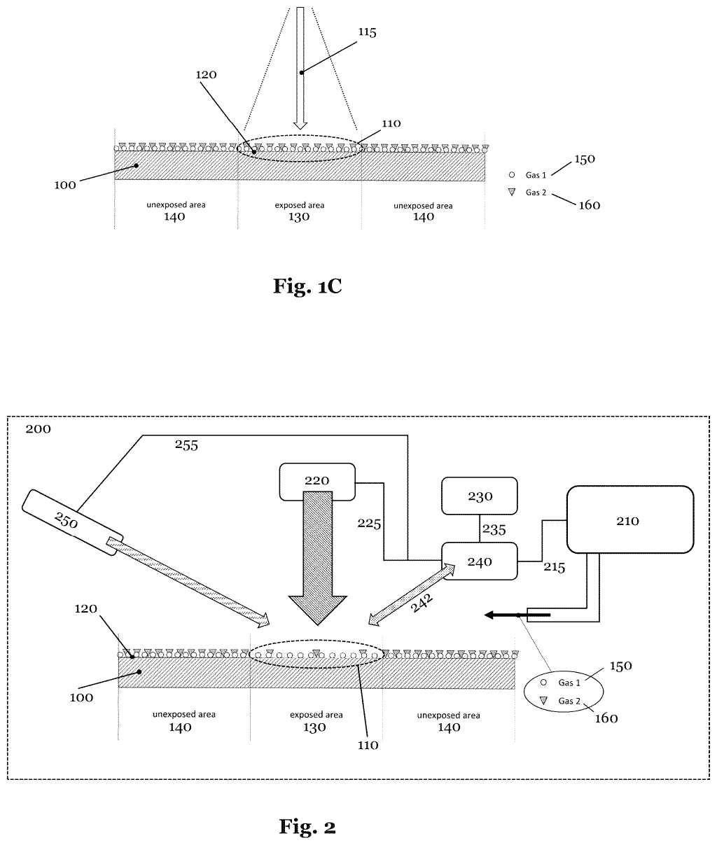

FIG. 2 schematically shows an embodiment 200 of an apparatus, as can be used for performing the method disclosed for processing a mask 100. For the sake of simplicity, the same reference signs with respect to the mask 100 and the gases 150 and 160, etc., as in FIGS. 1A-1C are used. The statements made in this respect therefore are still valid. However, this does not mean that the apparatus 200 can be used only for performing the specific embodiments of the disclosed method that were discussed as part of FIGS. 1A-1C.

Furthermore, a person skilled in the art will in principle be aware of apparatuses for mask processing and mask repair. For example, the applicant itself develops and sells apparatuses for mask repair. The apparatus 200 could for example proceed from one of these apparatuses, and for this reason the following text will not discuss all the specifications of the apparatus 200 in minute detail.

The apparatus 200 comprises means 210 for supplying a gas mixture including at least a first gas 150 (“Gas 1”) and a second gas 160 (“Gas 2”) at a reaction site 110 at a surface 120 of the mask 100, and means 220 for inducing a (chemical) reaction, which includes at least a first partial reaction and a second partial reaction, at the reaction site 110 by exposure of the reaction site 110 to a beam of energetic particles in a plurality of exposure intervals. As has already been described multiple times, the first partial reaction is promoted predominantly by the first gas 150 and the second partial reaction is promoted predominantly by the second gas 160. A gas refresh interval lies between the respective exposure intervals.

The particle beam can be for example a laser beam, electron beam or ion beam, and the means 220 can be configured correspondingly.

As a further component, the apparatus comprises means 230 for selecting the first partial reaction in order to increase the process rate thereof in relation to a process rate of the second partial reaction. The means 230 can be controllable and accessible for example via a user interface (hardware-side or software-site) and in this way allow the user a deliberate selection of a partial reaction in order to then be able to adjust and optimize the exposure parameters and/or other process parameters in a specific and targeted manner for this partial reaction.

The apparatus 200 furthermore comprises means 240 for selecting a time duration for the gas refresh interval, which brings about the relative increase in the process rate of the first partial reaction in comparison with the process rate of the second partial reaction. In particular, after the selection of the first partial reaction by the means 230, which can have a connection 235 to the means 240, the means 240 can automatically select a suitable time duration for the gas refresh interval in order to bring about the relative increase in the process rate of the first partial reaction. Several variants are conceivable herefor.

If the first gas 150 has, for example, a first addition duration to the reaction site 110 and the second gas 160 has a second addition duration, the means 240 can choose the time duration for the gas refresh interval on the basis of the first and second addition durations in a manner such that the relative increase in the process rate of the first partial reaction in comparison with the process rate of the second partial reaction is brought about. For example, the time duration can be selected to be shorter than the second addition duration or from the interval

I=[first addition duration; second addition duration].

The relevant values and data, for example the first and second addition durations for the first and second gases 150 and 160 (and possibly further gases) can be available to the apparatus 200 in the form of stored values and/or be obtained from a database.

In addition or alternatively, the apparatus can contain suitable means 242 in order to experimentally determine these and/or other values relevant for a suitable selection of the time duration, either during running operation (i.e. during the processing of the mask 100 itself) or in a dedicated test mode. The means 242 can comprise, for example, a sensor, which records in a test mode the concentration of the first and second gases 150 and 160 at the reaction site 110 depending on the duration of the gas refreshment that has passed. The means 242 can be connected to the means 240 or interact therewith in order to thus make possible by the means 240 an evaluation of such a series of measurements and thus a suitable selection of the time duration of the gas refresh interval.

In addition or alternatively, a manual selection of the time duration for the gas refresh interval can be possible via the means 240, for example via a user interface (hardware-side or software-side).

The means 240 can have a connection 215 to the means 210, which serves for the supply of gas, such that the supply of gas can take place according to the gas refresh interval selected by the means 240. The means 240 can also have a connection 225 to the means 220, which serves for inducing the processing reaction with its partial reactions by way of exposure, so that the exposure can be stopped during the gas refresh interval.

Alternatively or additionally to these components, the apparatus can furthermore have means 250 for the targeted heating of the reaction site 110 or of the mask 100 and/or mask surface 120 in this region. In particular, the means 250 can comprise a pulsed laser. Due to the targeted heating, as was already described above, it is possible to directly and/or indirectly influence the process rate of the first and second partial reactions. The means 250 can here be connected to the means 240 via a connection 255, with the result that the means 240 can interact for selecting the time duration for the gas refresh interval and the means 250 for heating in order to bring about the desired influence on the process rates of the first and second partial reactions.

In addition or alternatively, the means 250 can also be connected to or interact with the means 210 and 220 directly (not shown in FIG. 2) in order to influence the process rates independently of the means 240.

Finally, it is possible, for example in a computing or control unit of an apparatus for mask processing, to execute a computer program with instructions which cause the apparatus to carry out an embodiment of the disclosed method.

What is claimed is:

1. A method for processing a surface of an object, including:
a. supplying a gas mixture containing at least a first gas and a second gas to a reaction site at the surface of the object;
b. inducing a reaction, which includes at least a first partial reaction and a second partial reaction, at the reaction site by exposing the reaction site to a beam of energetic particles in a plurality of exposure intervals, wherein
b1. the first partial reaction is promoted primarily by the first gas and the second partial reaction is promoted primarily by the second gas, and wherein
b2. a gas refresh interval lies between the respective exposure intervals;
c. setting a first time duration for the gas refresh interval, as a result of which a process rate of the first partial reaction and a process rate of the second partial rate are present;
d. setting a second time duration for the gas refresh interval, which brings about a relative increase in the process rate of the first partial reaction in comparison with the process rate of the second partial reaction.

2. The method of claim 1, wherein the first gas has a first addition duration to the reaction site and the second gas has a second addition duration which is greater than the first addition duration, and wherein the second time duration for the gas refresh interval is set such that this is lower than the second addition duration.

3. The method of claim 1, wherein the second time duration for the gas refresh interval is set in a manner such that a concentration of the first gas, which has diffused to the reaction site during the gas refresh interval and been adsorbed at the surface, is greater than a concentration of the second gas.

4. The method of claim 1, wherein, proceeding from the second set time duration, shortening of the gas refresh interval leads to a further relative increase in the process rate of the first partial reaction in comparison with the process rate of the second partial reaction, while lengthening the gas refresh interval leads to a relative decrease in the process rate of the first partial reaction in comparison with the process rate of the second partial reaction.

5. The method of claim 1, further including adjusting one or more exposure parameters used for exposing the reaction site to the beam, specifically to optimize the first partial reaction.

6. The method of claim 5, wherein the one or more exposure parameters comprise a duration of the individual exposure intervals for the reaction site.

7. The method of claim 1, wherein the method comprises processing a plurality of reaction sites that are exposed to the beam of energetic particles during one or more respective exposure intervals within an exposure cycle.

8. The method of claim 7, further including adjusting one or more exposure parameters used for exposing the reaction site to the beam, specifically to optimize the first partial reaction, wherein the one or more exposure parameters comprise a duration of the respective exposure intervals for the individual reaction sites.

9. The method of claim 7, further including adjusting one or more exposure parameters used for exposing the reaction site to the beam, specifically to optimize the first partial reaction, wherein the one or more exposure parameters include a scanning pattern with which the individual reaction sites are exposed one after the other.

10. The method of claim 9, wherein the scanning pattern includes one or more subloops, which are run through more than once during an exposure cycle, with the result that the reaction sites contained in the one or more subloops are exposed multiple times within an exposure cycle.

11. The method of claim 1, further including heating the reaction site using a pulsed laser to influence the process rates of the individual partial reactions further.

12. The method of claim 1, wherein the beam of energetic particles is a laser beam.

13. The method of claim 1, wherein the beam of energetic particles is an electron beam.

14. The method of claim 1, wherein the beam of energetic particles is an ion beam.

15. The method of claim 1, wherein the first partial reaction comprises at least one of the following processes: a passivation process, an etching process, a deposition process, an oxidation process.

16. The method of claim 1, wherein the second partial reaction comprises at least one of the following processes: a passivation process, an activation process, an etching process, a deposition process.

17. The method of claim 1, wherein the reaction further includes a third partial reaction, which is promoted primarily by a third gas contained in the gas mixture.

18. The method of claim 1, wherein the object comprises a lithographic mask.

19. The method of claim 18, wherein the method serves for correcting a defect of the mask.

20. An apparatus for processing a surface of an object, in particular of a surface of a lithographic mask, including:
a. means for supplying a gas mixture containing at least a first gas and a second gas to a reaction site at the surface of the object;
b. means for inducing a reaction, which includes at least a first partial reaction and a second partial reaction, at the reaction site by exposing the reaction site to a beam of energetic particles in a plurality of exposure intervals, wherein
b1. the first partial reaction is promoted primarily by the first gas and the second partial reaction is promoted primarily by the second gas, and wherein
b2. a gas refresh interval lies between the respective exposure intervals;
c. means for automatically setting a first time duration for the gas refresh interval, as a result of which a process rate of the first partial reaction and a process rate of the second partial reaction are present; and
d. means for automatically setting a second duration for the gas refresh interval, which brings about a relative increase in the process rate of the first partial reaction in comparison with a process rate of the second partial reaction.

21. The apparatus of claim 20, wherein the first gas has a first addition duration to the reaction site and the second gas has a second addition duration, and wherein the means for automatically setting the second time duration for the gas refresh interval sets the time interval on the basis of the first and second addition durations in a manner such that the relative increase in the process rate of the first partial reaction in comparison with the process rate of the second partial reaction is brought about.

22. A computer program with instructions, which upon execution cause a computer and/or an apparatus for processing a surface of an object according to claim 20 to carry out a method for processing the surface of the object,
wherein the method comprises:
supplying a gas mixture containing at least a first gas and a second gas to a reaction site at the surface of the object;
inducing a reaction, which includes at least a first partial reaction and a second partial reaction, at the reaction site by exposing the reaction site to a beam of energetic particles in a plurality of exposure intervals;
wherein the first partial reaction is promoted primarily by the first gas and the second partial reaction is promoted primarily by the second gas;
wherein a gas refresh interval lies between the respective exposure intervals;
setting a first time duration for the gas refresh interval, as a result of which a process rate of the first partial reaction and a process rate of the second partial rate are present; and
setting a second time duration for the gas refresh interval, which brings about a relative increase in the process rate of the first partial reaction in comparison with the process rate of the second partial reaction.
